(19) United States
(12) Patent Application Publication
(10) Pub. No.: US 2021/0193965 A1
(43) Pub. Date: Jun. 24, 2021

(54) DISPLAY SUBSTRATE, DISPLAY APPARATUS AND METHOD OF ENCAPSULATION DISPLAY DEVICE

(71) Applicants: Hefei BOE Optoelectronics Technology Co., Ltd., Hefei, Anhui (CN); BOE Technology Group Co., Ltd., Beijing (CN)

(72) Inventors: Kui Gong, Beijing (CN); Zhihai Zhang, Beijing (CN); Xianxue Duan, Beijing (CN); Jilong Li, Beijing (CN); Haifeng Cui, Beijing (CN)

(21) Appl. No.: 16/756,163

(22) PCT Filed: May 14, 2019
(86) PCT No.: PCT/CN2019/086882

§ 371 Date: Apr. 15, 2020

(30) Foreign Application Priority Data
May 31, 2018 (CN) 201810550968.X

(51) Int. Cl. H01L 51/52; H01L 27/32; H01L 51/56

(52) U.S. Cl. CPC H01L 51/5268; H01L 27/3244; H01L 2251/5315; H01L 51/56; H01L 2227/323; H01L 51/5253

(57) ABSTRACT

Provided is a display substrate including: a base substrate, and a light-emitting device and an encapsulating structure which are disposed on the base substrate in sequence in a direction away from the base substrate, wherein the encapsulating structure includes an organic scattering layer and an inorganic barrier layer disposed on at least one side of the organic scattering layer, and the organic scattering layer has bubble structures therein. By arranging an organic scattering layer in the encapsulating structure, the optical coupling efficiency of the display substrate is improved while the encapsulating effect of the encapsulating structure is ensured.

### CROSS-REFERENCE TO RELATED APPLICATION

The present application is a 371 of PCT/CN2019/086882, filed on May 14, 2019, which claims priority to Chinese Patent Application No. 201810550968.X, filed on May 31, 2018 and entitled “DISPLAY PANEL AND ENCAPSULATION METHOD THEREOF, AND DISPLAY DEVICE”, which is incorporated herein by reference in its entirety.

### TECHNICAL FIELD

The present disclosure relates to the field of a display technologies, and more particularly to a display substrate, a display apparatus and a method of encapsulating a display device.

### BACKGROUND

The encapsulation of an organic light-emitting diode (OLED) device is important because when the organic light-emitting material in the OLED device is in contact with water and oxygen, the light-emitting effect of the organic light-emitting material will be affected, thereby influencing the quality and service life of the OLED device.

### SUMMARY

The present disclosure provides a display substrate, a display apparatus and a method of encapsulating a display device. The technical solutions are as follows:

In one aspect, a display substrate is provided. The display substrate includes:

a base substrate, and a light-emitting device and an encapsulating structure which are disposed on the base substrate in sequence in a direction away from the base substrate, wherein

the encapsulating structure includes an organic scattering layer and an inorganic barrier layer located on at least one side of the organic scattering layer; and the organic scattering layer has bubble structures therein.

Optionally, a material for preparing the organic scattering layer includes epoxy resin.

Optionally, the inorganic barrier layer includes a first inorganic barrier layer and a second inorganic barrier layer; the first inorganic barrier layer, the organic scattering layer and the second inorganic barrier layer included in the encapsulating structure are disposed in sequence in a direction away from the base substrate.

Optionally, the encapsulating structure further includes a first organic buffer layer; and the first organic buffer layer is located between the organic scattering layer and the second inorganic barrier layer.

Optionally, the encapsulating structure further includes at least one laminated structure located on a side of the second inorganic barrier layer away from the base substrate; and each laminated structure includes a second organic buffer layer and a third inorganic barrier layer that are laminated in a direction away from the base substrate.

Optionally, a material for preparing the inorganic barrier layer includes at least one selected from a group consisting of metal oxide, metal sulfide, and metal nitride.

Optionally, the display substrate further includes a thin film transistor located between the base substrate and the light-emitting device.

Optionally, the light-emitting device is a top-emission type light-emitting device.

Optionally, the light-emitting device is one of an organic light-emitting diode (OLED) device and a quantum dot light-emitting diode (QLED) device.

In another aspect, a display apparatus is provided. The apparatus includes the display substrate according to any one of the above aspect.

In yet another aspect, a method of encapsulating a display device is provided. The method includes:

providing a display device, the display device including a base substrate and a light-emitting device located on the base substrate; and

forming an encapsulating structure on a side of the light-emitting device away from the base substrate, the encapsulating structure including an organic scattering layer and an inorganic barrier layer located on at least one side of the organic scattering layer, and the organic scattering layer having bubble structures therein.

Optionally, the forming the encapsulating structure on the side of the light-emitting device away from the base substrate includes:

forming a first inorganic barrier layer on the side of the light-emitting device away from the base substrate;

forming an organic material layer on a side of the first inorganic barrier layer away from the base substrate by using an organic material doped with a foaming agent;

performing foaming treatment on the organic material layer to obtain the organic scattering layer; and

forming a second inorganic barrier layer on a side of the organic scattering layer away from the base substrate.

Optionally, a melting point of the organic material is lower than a minimum decomposition temperature of the foaming agent, and the performing foaming treatment on the organic material layer includes:

increasing a temperature of the organic material layer until the temperature of the organic material layer is within a decomposition temperature range of the foaming agent, such that the foaming agent is decomposed to release a gas, and the gas forms the bubble structures within the molten-state organic material layer.

Optionally, the increasing the temperature of the organic material layer includes:

increasing the temperature of the organic material layer by means of light irradiation.

Optionally, the increasing the temperature of the organic material layer includes:

increasing the temperature of the organic material layer by means of heating.

Optionally, a doping rate of the foaming agent in the organic material is between 0.5% and 2%.

Optionally, the foaming agent includes a main foaming agent, and the main foaming agent includes at least one selected from a group consisting of azobisformamide, diisopropyl azodiformate, and p-toluenesulfonyl semicarbazide.

Optionally, the foaming agent further includes a foaming aid, and the foaming aid includes at least one selected from a group consisting of zinc oxide and zinc stearate.

Optionally, after performing the foaming treatment on the organic material layer to obtain the organic scattering layer, the method further includes:

forming a first organic buffer layer on a side of the organic scattering layer away from the base substrate; and

the forming the second inorganic barrier layer on a side of the organic scattering layer away from the base substrate includes:

forming the second inorganic barrier layer on the side of the first organic buffer layer away from the base substrate.

Optionally, after forming the second inorganic barrier layer on the side of the organic scattering layer away from the base substrate, the method further includes:

forming a second organic buffer layer on a side of the second inorganic barrier layer away from the base substrate; and

forming a third inorganic barrier layer on a side of the second organic buffer layer away from the base substrate.

### BRIEF DESCRIPTION OF THE DRAWINGS

FIG. 1 is a schematic structural diagram of an OLED display substrate known to the inventors;

FIG. 2 is a schematic structural diagram of a display substrate provided by an embodiment of the present disclosure;

FIG. 3 is a schematic structural diagram of another display substrate provided by an embodiment of the present disclosure;

FIG. 4 is a schematic structural diagram of yet another display substrate provided by an embodiment of the present disclosure;

FIG. 5 is a flowchart of a method of encapsulating a display substrate provided by an embodiment of the present disclosure; and

FIG. 6 is a flowchart of another method of encapsulating a display substrate provided by an embodiment of the present disclosure.

### DETAILED DESCRIPTION

The present disclosure will be described in further detail with reference to the accompanying drawings, to present the objects, technical solutions, and advantages of the present disclosure more clearly.

An Organic Light-Emitting Diode (OLED) device is a current-type light-emitting device and is more and more popular in the field of high-performance display, due to its properties such as low power consumption, self-light-emission, fast response (with a response time of about 1 microsecond), wide viewing angle (with a viewing angle up to more than 175 degrees), thin thickness and feasibility of being manufactured into a large-sized flexible display panel, etc.

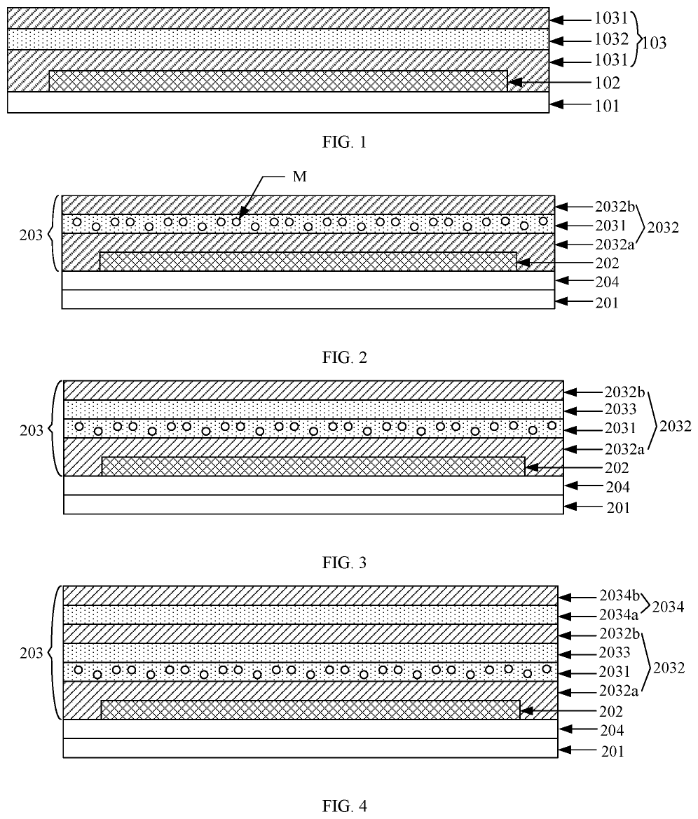

Currently, laminated thin film is generally used when encapsulating the flexible OLED device to obtain an OLED display substrate. FIG. 1 is a schematic structural diagram of an OLED display substrate known to the inventors. As shown in FIG. 1, the OLED display substrate includes: an array substrate 101, and an OLED device 102 and a laminated thin film 103 which are disposed in sequence in a direction away from the array substrate 101. An orthographic projection of the laminated thin film 103 onto the array substrate 101 covers an orthographic projection of the OLED device 102 onto the array substrate 101. Here, the laminated thin film 103 includes inorganic barrier layers 1031 and organic buffer layers 1032 which are laminated in an alternate manner. The inorganic barrier layers 1031 are configured to block water and oxygen from entering the OLED device. The organic buffer layers 1032 are configured to increase a length of a permeation channel and release a stress between the inorganic barrier layers 1031, and have a flattening function.

However, when the laminated thin film is disposed on a light-emitting side of the OLED device, the light coupling efficiency of the OLED display substrate will be relatively low, thereby resulting in a relatively low light-emitting efficiency of the OLED display substrate.

FIG. 2 is a schematic structural diagram of a display substrate provided by an embodiment of the present disclosure. As shown in FIG. 2, the display substrate includes:

a base substrate 201, and a light-emitting device 202 and an encapsulating structure 203 which are disposed on the base substrate 201 in sequence in a direction away from the base substrate 201. The encapsulating structure 203 includes an organic scattering layer 2031 and an inorganic barrier layer 2032 located on at least one side of the organic scattering layer 2031. The organic scattering layer 2031 has bubble structures M therein.

Optionally, the encapsulating structure may include an organic scattering layer and an inorganic barrier layer located on at least one side of the organic scattering layer; or, the encapsulating structure may include an organic scattering layer and an inorganic barrier layer located on a side of the organic scattering layer close to the base substrate; or, the encapsulating structure may include an organic scattering layer and an inorganic barrier layer located on a side of the organic scattering layer away from the base substrate; or the encapsulating structure may include an organic scattering layer and inorganic barrier layers respectively located on two sides of the organic scattering layer. The following embodiments of the present disclosure will be described by taking the case that the encapsulating structure includes an organic scattering layer and inorganic barrier layers respectively located on two sides of the organic scattering layer as an example.

It should be noted that the light-emitting device provided by the embodiment of the present disclosure is a top-emission type light-emitting device. That is, the display substrate is in a top-emission type structure. The light-emitting device may be one of an OLED device and a quantum dot light emitting diode (QLED) device. The light-emitting device may include an anode, a hole injection layer, a hole transport layer, a light-emitting material layer, an electron transport layer, an electron injection layer, and a cathode which are disposed in a laminated manner. When the light-emitting device is the OLED device, the light-emitting material layer is an organic light-emitting material layer. When the light-emitting device is the QLED device, the light-emitting material layer is a quantum dot material layer.

Optionally, the inorganic barrier layers are configured to block water and oxygen from entering the light-emitting device, and have a protective effect on the light-emitting device in blocking water and oxygen. The material for preparing the inorganic barrier layers includes at least one selected from a group consisting of metal oxide, metal sulfide, and metal nitride. For example, the metal oxide may include calcium oxide, tantalum pentoxide, titanium dioxide, zirconia, copper oxide, zinc oxide, aluminum oxide, tin oxide, and the like. Metal sulfide may include titanium disulfide, iron sulfide, chromium sulfide, copper sulfide, zinc sulfide, tin disulfide, lead sulfide, and the like. The metal nitride may include silicon nitride, aluminum nitride, and the like.

Optionally, referring to FIG. 2, the inorganic barrier layers 2032 include a first inorganic barrier layer 2032a and a second inorganic barrier layer 2032b. Thus, the encapsulating structure 203 includes the first inorganic barrier layer 2032a, the organic scattering layer 2031 and the second inorganic barrier layer 2032b which are disposed in sequence in a direction away from the base substrate 201. The organic scattering layer can serve as a buffer layer between the first inorganic barrier layer and the second inorganic barrier layer, so as to increase a permeation channel of water and oxygen and release the stress between the inorganic barrier layers. Optionally, a material for preparing the organic scattering layer includes epoxy resin.

In summary, in the display substrate provided by the embodiment of the present disclosure, the organic scattering layer is disposed in the encapsulating structure. As the organic scattering layer has a plurality of bubble structures therein, when light emitted by the light-emitting device passes through the organic scattering layer, the bubble structures can scatter light, so that the light can be emitted uniformly from the display substrate. On the one hand, the light coupling efficiency of the display substrate is improved, and the light-emitting efficiency of the display substrate is also improved while ensuring that the encapsulating structure can effectively prevent water and oxygen from entering the light-emitting device. On the other hand, the problem of limited viewing angle of the top-emission type display substrate due to microcavity effect is improved, so that the display content on the display substrate can be seen from all angles, and the display effect of the display substrate is improved.

Optionally, FIG. 3 is a schematic structural diagram of another display substrate provided in an embodiment of the present disclosure. As shown in FIG. 3, the encapsulating structure 203 further includes a first organic buffer layer 2033. The first organic buffer layer 2033 is located between the organic scattering layer 2031 and the second inorganic barrier layer 2032b.

Here, the material for preparing the first organic buffer layer may be the same as the organic material in the organic scattering layer, or may also be different from the organic material in the organic scattering layer. Optionally, the material for preparing the first organic buffer layer may include at least one selected from the group consisting of polyethylene terephthalate (PET), poly(ethylene naphthalate) (polyethylene naphthalate two formic acid glycol ester, PEN), polycarbonate (PC), polyimide (PI), polyvinyl chloride (PVC), polystyrene (PS), polymethyl methacrylate (PMMA), polybutylene terephthalate (PBT), polysulfone resin (PSO), poly(ethylene succinate), polyethylene (PE), polypropylene (PP), polyamide (PA), polytetrafluoroethylene (PTFE), and epoxy resin.

It should be noted that, due to the bubble structures in the organic scattering layer, the flatness degree of the surface of the organic scattering layer is relatively low. Thus, the first organic buffer layer can have a flattening function, and can also increase the length of a water and oxygen permeation channel and release the stress between the inorganic barrier layers.

Optionally, FIG. 4 is a schematic structural diagram of a yet another display substrate provided in an embodiment of the present disclosure. As shown in FIG. 4, the encapsulating structure 203 further includes at least one laminated structure 2034 located on a side of the second inorganic barrier layer 2032b away from the base substrate 201. Each of the laminated structures 2034 includes a second organic buffer layer 2034a and a third inorganic barrier layer 2034b that are laminated in a direction away from the base substrate 201. The embodiment of the present disclosure will be described by taking a case that the encapsulating structure in FIG. 4 includes one laminated structure as an example. The encapsulating structure may also include two, three or more laminated structures, which is not limited in the embodiment of the present disclosure.

It should be noted that, for the material of the second organic buffer layer, a reference can be made to the material of the first organic buffer layer, and for the material of the third inorganic barrier layer, a reference can be made to the material of the above-mentioned inorganic barrier layer, which is not described in the embodiment of the present disclosure. By arranging an organic buffer layer and an inorganic barrier layer in a laminated manner on a side of the first inorganic barrier layer away from the base substrate, the ability of the encapsulating structure in blocking water and oxygen can be further improved.

Optionally, referring to FIG. 2 to FIG. 4, the display substrate may further include a thin film transistor 204 located between the base substrate 201 and the light-emitting device 202. The thin film transistor is configured to control the light-emitting device to emit light. The thin film transistor may be a top-gate type thin film transistor or a bottom-gate type thin film transistor, which is not limited in the embodiment of the present disclosure.

In summary, in the display substrate provided by the embodiment of the present disclosure, the organic scattering layer is disposed in the encapsulating structure. As the organic scattering layer has a plurality of bubble structures therein, when light emitted by the light-emitting device passes through the organic scattering layer, the bubble structures can scatter light, so that the light can be emitted uniformly from the display substrate. On the one hand, the light coupling efficiency of the display substrate is improved, and the light-emitting efficiency of the display substrate is also improved while ensuring that the encapsulating structure can effectively prevent water and oxygen from entering the light-emitting device. On the other hand, the problem of limited viewing angle of the top-emission type display substrate due to microcavity effect is improved, so that the display content on the display substrate can be seen from all angles, and the display effect of the display substrate is improved.

An embodiment of the present disclosure provides a display apparatus, which may include a display substrate as shown in any one of FIG. 2 to FIG. 4.

Optionally, the display apparatus may be a flexible top-emission type OLED display apparatus or a flexible top-emission type QLED display apparatus.

Optionally, the display apparatus may be any product or component having a display function, such as a display panel, an electronic paper, a mobile phone, a tablet computer, a television, a display, a laptop computer, a digital photo frame, a navigator, or the like.

In summary, in the display apparatus provided by the embodiment of the present disclosure, the organic scattering layer is disposed in the encapsulating structure. As the organic scattering layer has a plurality of bubble structures therein, when light emitted by the light-emitting device passes through the organic scattering layer, the bubble structures can scatter light, so that the light can be emitted uniformly from the display substrate. On the one hand, the light coupling efficiency of the display substrate is improved, and the light-emitting efficiency of the display substrate is also improved while ensuring that the encapsulating structure can effectively prevent water and oxygen from entering the light-emitting device. On the other hand, the problem of limited viewing angle of the top-emission type display substrate due to microcavity effect is improved, so that the display content on the display apparatus can be seen from all angles, and the display effect of the display apparatus is improved.

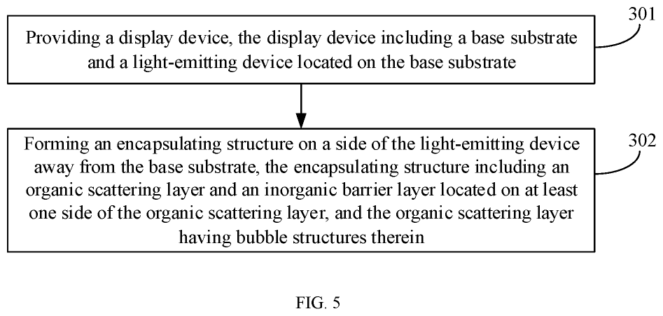

FIG. 5 is a flowchart of a method of encapsulating a display device as provided by an embodiment of the present disclosure. As shown in FIG. 5, the method includes the following steps.

In step 301, a display device is provided, the display device including a base substrate and a light-emitting device located on the base substrate.

In step 302, an encapsulating structure is formed on a side of the light-emitting device away from the base substrate, the encapsulating structure including an organic scattering layer and an inorganic barrier layer located on at least one side of the organic scattering layer, and the organic scattering layer having bubble structures therein.

Optionally, referring to FIG. 2, the encapsulating structure 203 includes the first inorganic barrier layer 2032a, the organic scattering layer 2031 and the second inorganic barrier layer 2032b which are disposed in sequence in a direction away from the base substrate 201. The implementation process of the step 302 may include the following steps.

In step 3021, a first inorganic barrier layer is formed on a side of the light-emitting device away from the base substrate.

In step 3022, an organic material layer is formed on a side of the first inorganic barrier layer away from the base substrate by using an organic material doped with a foaming agent.

In step 3023, foaming treatment is performed on the organic material layer to obtain the organic scattering layer.

In step 3024, a second inorganic barrier layer is formed on a side of the organic scattering layer away from the base substrate.

In summary, in the method of encapsulating a display substrate provided by the embodiment of the present disclosure, the organic scattering layer is disposed in the encapsulating structure. As the organic scattering layer has a plurality of bubble structures therein, when light emitted by the light-emitting device passes through the organic scattering layer, the bubble structures can scatter light, so that the light can be emitted uniformly from the display substrate. On the one hand, the light coupling efficiency of the display substrate is improved, and the light-emitting efficiency of the display substrate is also improved while ensuring that the encapsulating structure can effectively prevent water and oxygen from entering the light-emitting device. On the other hand, the problem of limited viewing angle of the top-emission type display substrate due to microcavity effect is improved, so that the display content on the display substrate can be seen from all angles, and the display effect of the display substrate is improved.

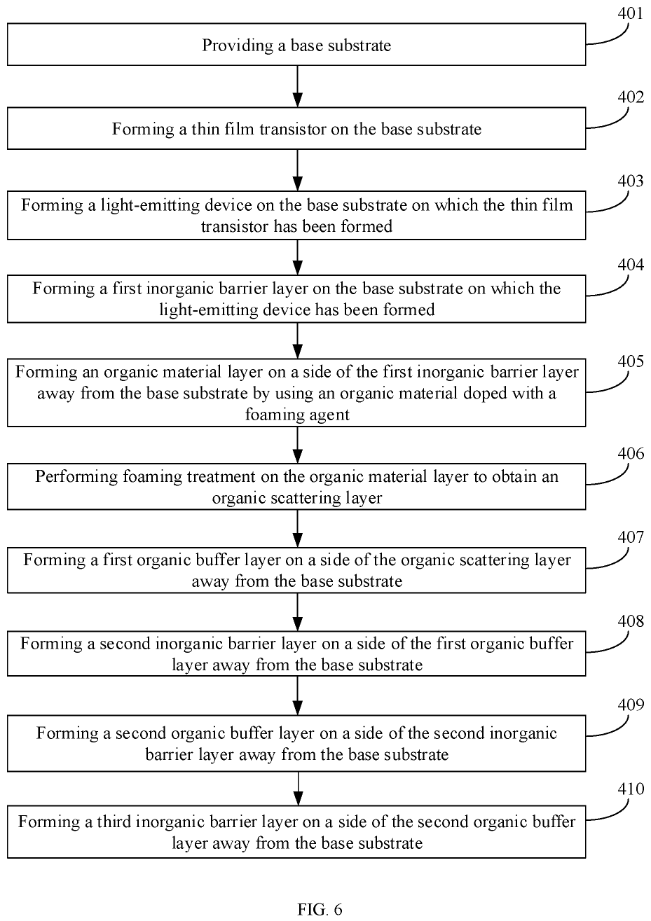

FIG. 6 is a flowchart of another method of encapsulating a display substrate provided in an embodiment of the present disclosure. As shown in FIG. 6, the method includes the following steps.

In step 401, a base substrate is provided.

Optionally, the base substrate may be made of a transparent material such as glass, a silicon wafer, quartz, plastic, or the like, and can be cleaned by standard methods.

In step 402, a thin film transistor is formed on the base substrate.

Optionally, the thin film transistor may be a top-gate type thin film transistor or a bottom-gate type thin film transistor, which is not limited in the embodiment of the present disclosure.

In step 403, a light-emitting device is formed on the base substrate on which the thin film transistor has been formed.

Optionally, the light-emitting device may be an OLED device or a QLED device. The light-emitting device may include an anode, a hole injection layer, a hole transport layer, a light-emitting material layer, an electron transport layer, an electron injection layer, and a cathode which are disposed in a laminated manner.

Exemplarily, a metal layer may be formed on the base substrate on which the thin film transistor has been formed, by depositing indium tin oxide (ITO), and an anode may be formed by a patterning process. An acrylic layer may be formed on the base substrate on which the anode has been formed, by spin-coating and depositing an acrylic material, and a pixel defining layer may be formed by processes such as photoetching, curing and the like. Further, after the side of the pixel defining layer away from the base substrate is treated by a plasma technology, a hole injection layer and a hole transport layer are prepared by using an inkjet printing process, respectively. The hole injection layer may be prepared from a thermoplastic polymer PEDOT: PSS (poly (3,4-ethylenedioxythiophene) polystyrene sulfonate). The hole transport layer may be prepared from 1,2,4,5-tetrakis (trifluoromethyl) benzene (TFB). Then, a light-emitting material layer (such as a quantum dot material layer) may be formed by printing. An electron transport layer and the electron injection layer may be formed by printing or sputtering. The cathode may be formed by depositing ITO.

In step 404, a first inorganic barrier layer is formed on the base substrate on which the light-emitting device has been formed.

Optionally, the first inorganic barrier layer may be formed on the base substrate on which the light-emitting device has been formed, by plasma enhanced chemical vapor deposition (PECVD), atomic layer deposition, laser pulse deposition, or sputtering.

It should be noted that, for the material of the first inorganic barrier layer, a reference can be made to the material of the inorganic barrier layer described in the apparatus embodiment, which is not described in the embodiment of the present disclosure.

In step 405, an organic material layer is formed on a side of the first inorganic barrier layer away from the base substrate by using an organic material doped with a foaming agent.

Optionally, the organic material doped with the foaming agent can be adopted to form the organic material layer on a side of the first inorganic barrier layer away from the base substrate by means of coating, printing or depositing. The organic material layer may be made of an organic material with a lower melting point (such as epoxy resin).

In the embodiment of the present disclosure, the foaming agents may take various forms. The foaming agent may include a main foaming agent. The main foaming agent includes at least one selected from a group consisting of azobisformamide (AC), diisopropyl azodicarboxylate, and p-toluenesulfonyl semicarbazide. The main foaming agent is used to decompose and generate a gas during the foaming treatment. In order to further promote the decomposition of the main foaming agent, optionally, the foaming agent may include a main foaming agent and a foaming aid. The foaming aid is used to adjust the gas volume as generated and reaction rate of the main foaming agent when the main foaming agent is subjected to a foaming treatment. Optionally, the foaming aid may include at least one selected from a group consisting of zinc oxide and zinc stearate.

Exemplarily, AC is a desirable main foaming agent, because it has a high decomposition temperature of about 200° C., which is much higher than the melting point of commonly used organic materials (such as organic resin), and also has a high gas volume and is non-toxic. Meanwhile, zinc oxide or zinc stearate can be selected as a foaming aid for aiding the decomposition of AC. Zinc oxide or zinc stearate can promote AC decomposition, so as to increase the gas volume and accelerate the decomposition rate of AC.

In step 406, foaming treatment is performed on the organic material layer to obtain the organic scattering layer.

It should be noted that the way of performing the foaming treatment depends on the chemical and physical properties of the foaming agent doped in the organic material layer. Optionally, no matter whether the foaming agent includes a single type of main foaming agent, or includes a main foaming agent and a foaming aid, when a melting point of the organic material is lower than a minimum decomposition temperature of the foaming agent, the following method may be selected for performing the foaming treatment on the organic material layer. The method includes:

increasing the temperature of the organic material layer until the temperature of the organic material layer is within a decomposition temperature range of the foaming agent, such that the foaming agent is decomposed to release a gas, and the gas forms the bubble structures inside the organic material layer which is in a molten state.

Optionally, the temperature of the organic material layer can be raised by means of light irradiation or heating. Here, the way of light irradiation includes ultraviolet irradiation or specific ray radiation.

It should be noted that as a plurality of bubble structures are disposed in the organic scattering layer, when light emitted by the light-emitting device passes through the organic scattering layer, it can be scattered by the bubble structures, so that the light can be emitted uniformly from the display substrate, thereby improving the optical coupling efficiency and in turn the light-emitting efficiency of the display substrate.

In the embodiment of the present disclosure, the amount of the foaming agent doped in the organic material layer needs to be controlled within a certain range. If the doped foaming agent is excessive, a large amount of gas will be generated when the foaming agent is decomposed, resulting in too many bubble structures being formed, which may affect the transmittance of light emitted from the light-emitting device. However, if the amount of the doped foaming agent is too low, the purpose of improving light coupling efficiency cannot be achieved. Optionally, a doping rate of the foaming agent in the organic material is between 0.5% and 2%.

In step 407, a first organic buffer layer is formed on a side of the organic scattering layer away from the base substrate.

As the organic scattering layer is obtained by the bubble structures generated through decomposing the foaming agent in the organic material layer, the flatness degree of the surface of the organic scattering layer is generally low. For the purpose of planarization, the first organic buffer layer may be formed on a side of the organic scattering layer away from the base substrate by means of coating, printing or depositing.

Optionally, for the material of the first organic buffer layer, a reference can be made to the descriptions of the apparatuses, which is not described in the embodiment of the present disclosure.

In step 408, a second inorganic barrier layer is formed on a side of the first organic buffer layer away from the base substrate.

Optionally, for the implementation process of this step, a reference can be made to step 404, which is not repeated in the embodiment of the present disclosure.

In step 409, a second organic buffer layer is formed on a side of the second inorganic barrier layer away from the base substrate.

Optionally, for the implementation process of this step, a reference can be made to step 407, which is not repeated in the embodiment of the present disclosure.

In step 410, a third inorganic barrier layer is formed on a side of the second organic buffer layer away from the base substrate.

Optionally, for the implementation process of this step, a reference can be made to step 404, which is not repeated in the embodiment of the present disclosure.

It should be noted that the sequence of the steps in the method of encapsulating the display substrate provided by the embodiments of the present disclosure may be appropriately adjusted, and the steps may be deleted or added accordingly based on the specific situation. For example, step 407 may be not performed, or after step 410, an organic buffer layer and an inorganic barrier layer may be further disposed in a laminated manner. Any variations of the method easily derived by a person skilled in the art within the technical scope disclosed in the present disclosure should be covered by the protection scope of the present disclosure, which is not repeated here.

In summary, in the method of encapsulating the display substrate provided by the embodiment of the present disclosure, the organic scattering layer is disposed in the encapsulating structure. As the organic scattering layer has a plurality of bubble structures therein, when light emitted by the light-emitting device passes through the organic scattering layer, the bubble structures can scatter light, so that the light can be emitted uniformly from the display substrate. On the one hand, the light coupling efficiency of the display substrate is improved, and the light-emitting efficiency of the display substrate is also improved while ensuring that the encapsulating structure can effectively prevent water and oxygen from entering the light-emitting device. On the other hand, the problem of limited viewing angle of the top-emission type display substrate due to microcavity effect is improved, so that the display content on the display substrate can be seen from all angles, and the display effect of the display substrate is improved.

The foregoing descriptions are merely optional embodiments of the present disclosure, and are not intended to limit the present disclosure. Within the spirit and principles of the disclosure, any modifications, equivalent substitutions, improvements, etc., are within the protection scope of the present disclosure.

What is claimed is:

1. A display substrate, comprising:
a base substrate, and a light-emitting device and an encapsulating structure which are disposed on the base substrate in sequence in a direction away from the base substrate, wherein
the encapsulating structure comprises an organic scattering layer and an inorganic barrier layer located on at least one side of the organic scattering layer, and the organic scattering layer has bubble structures therein.

2. The display substrate according to claim 1, wherein a material for preparing the organic scattering layer includes epoxy resin.

3. The display substrate according to claim 1, wherein the inorganic barrier layer comprises a first inorganic barrier layer and a second inorganic barrier layer; the first inorganic barrier layer, the organic scattering layer and the second inorganic barrier layer comprised in the encapsulating structure are disposed in sequence in a direction away from the base substrate.

4. The display substrate according to claim 3, wherein the encapsulating structure further comprises a first organic buffer layer; and the first organic buffer layer is located between the organic scattering layer and the second inorganic barrier layer.

5. The display substrate according to claim 3, wherein the encapsulating structure further comprises at least one laminated structure located on a side of the second inorganic barrier layer away from the base substrate; and each laminated structure comprises a second organic buffer layer and a third inorganic barrier layer that are laminated in a direction away from the base substrate.

6. The display substrate according to claim 1, wherein a material for preparing the inorganic barrier layer includes at least one selected from a group consisting of metal oxide, metal sulfide, and metal nitride.

7. The display substrate according to claim 1, further comprising a thin film transistor located between the base substrate and the light-emitting device.

8. The display substrate according to claim 1, wherein the light-emitting device is a top-emission type light-emitting device.

9. The display substrate according to claim 1, wherein the light-emitting device is one of an organic light-emitting diode OLED device and a quantum dot light-emitting diode QLED device.

10. A display apparatus, comprising a display substrate, wherein the display substrate comprises:
a base substrate, and a light-emitting device and an encapsulating structure which are disposed on the base substrate in sequence in a direction away from the base substrate, wherein
the encapsulating structure comprises an organic scattering layer and an inorganic barrier layer located on at least one side of the organic scattering layer, and the organic scattering layer has bubble structures therein.

11. A method of encapsulating a display device, comprising:
providing a display device, the display device comprising a base substrate and a light-emitting device located on the base substrate; and
forming an encapsulating structure on a side of the light-emitting device away from the base substrate, the encapsulating structure comprising an organic scattering layer and an inorganic barrier layer located on at least one side of the organic scattering layer, and the organic scattering layer having bubble structures therein.

12. The method according to claim 11, wherein the forming the encapsulating structure on the side of the light-emitting device away from the base substrate comprises:
forming a first inorganic barrier layer on the side of the light-emitting device away from the base substrate;
forming an organic material layer on a side of the first inorganic barrier layer away from the base substrate by using an organic material doped with a foaming agent;
performing foaming treatment on the organic material layer to obtain the organic scattering layer; and
forming a second inorganic barrier layer on a side of the organic scattering layer away from the base substrate.

13. The method according to claim 12, wherein a melting point of the organic material is lower than a minimum decomposition temperature of the foaming agent, and the performing foaming treatment on the organic material layer comprises:
increasing a temperature of the organic material layer until the temperature of the organic material layer is within a decomposition temperature range of the foaming agent, such that the foaming agent is decomposed to release a gas, and the gas forms the bubble structures within the molten organic material layer.

14. The method according to claim 13, wherein the increasing the temperature of the organic material layer comprises:
increasing the temperature of the organic material layer by means of light irradiation.

15. The method according to claim 13, wherein the increasing the temperature of the organic material layer comprises:
increasing the temperature of the organic material layer by means of heating.

16. The method according to claim 12, wherein a doping rate of the foaming agent in the organic material is between 0.5% and 2%.

17. The method according to claim 12, wherein the foaming agent comprises a main foaming agent, and the main foaming agent comprises at least one selected from a group consisting of azobisformamide, diisopropyl azodiformate, and p-toluenesulfonyl semicarbazide.

18. The method according to claim 17, wherein the foaming agent further comprises a foaming aid, and the foaming aid comprises at least one selected from a group consisting of zinc oxide and zinc stearate.

19. The method according to claim 12, after performing the foaming treatment on the organic material layer to obtain the organic scattering layer, the method further comprises:
forming a first organic buffer layer on a side of the organic scattering layer away from the base substrate; and
the forming the second inorganic barrier layer on a side of the organic scattering layer away from the base substrate comprises:
forming the second inorganic barrier layer on the side of the first organic buffer layer away from the base substrate.

20. The method according to claim 12, after forming the second inorganic barrier layer on the side of the organic scattering layer away from the base substrate, the method further comprises:
forming a second organic buffer layer on a side of the second inorganic barrier layer away from the base substrate; and
forming a third inorganic barrier layer on a side of the second organic buffer layer away from the base substrate.
